(19) United States
(12) Patent Application Publication
(10) Pub. No.: US 2012/0319252 A1
(43) Pub. Date: Dec. 20, 2012

(54) METHOD FOR MANUFACTURING SEMICONDUCTOR DEVICE, SUBSTRATE PROCESSING APPARATUS, AND SEMICONDUCTOR DEVICE

(75) Inventor: Hirohisa Yamazaki, Toyama-shi (JP)

(73) Assignee: HITACHI KOKUSAI ELECTRIC INC., Tokyo (JP)

(21) Appl. No.: 13/575,798

(22) PCT Filed: Jan. 20, 2011
(86) PCT No.: PCT/JP2011/050967

§ 371 Date: Aug. 31, 2012

(30) Foreign Application Priority Data
Jan. 29, 2010 (JP) 2010-018907

(51) Int. Cl. H01L 29/06; H01L 21/66; C23C 16/455; H01L 21/316

(52) U.S. Cl. 257/646; 438/5; 118/715; 257/E21.271; 257/E21.528; 257/E29.006

(57) ABSTRACT

A method for manufacturing a semiconductor device includes performing a cycle a predetermined number of times to form a film on a substrate. The cycle includes feeding a first material containing a first element, to be adsorbed on a substrate surface, to a processing chamber where the substrate is accommodated; feeding a second material containing a second element, adsorbed on the substrate surface, to the processing chamber after the adsorption of the first material; feeding a third material containing a third element to the processing chamber, so that the substrate surface is modified; and removing an atmosphere in the processing chamber. A content of the second element in the film is controlled by adjusting an adsorption quantity of the first material and an adsorption quantity of the second material with respect to a saturated adsorption quantity of the first material adsorbed on the substrate surface.

### TECHNICAL FIELD

The present invention relates to a method for manufacturing a semiconductor device for manufacturing IC and other semiconductor elements from a wafer of silicon or the like, as well as a substrate processing apparatus and a semiconductor device.

### BACKGROUND ART

In recent years, with the increase in the density of semiconductor devices, there is a demand on developing even thinner insulating films when the devices are formed. However, though the insulating film is made thinner, a tunnel current flows, so that as the thickness is significantly decreased, there is a requirement that no tunnel effect actually take place. As far as the capacitor materials are concerned, attention has been paid on the high dielectric constant metal oxides, such as hafnium oxide film, zirconium oxide film, etc., with high dielectric constant. For example, while it is difficult to form a silicon oxide film with a thickness of 1.6 nm due to electrical restrictions, it is possible to realize a similar dielectric constant with a hafnium oxide film as a high dielectric constant (High-k) film with a thickness of 4.5 nm. In this way, it is possible to adopt the high dielectric constant (High-k) films, such as hafnium oxide film, zirconium oxide film, etc., as the insulating films mainly in capacitors of DRAM elements in the order in the range of 90-50 nm. As a method for forming the high dielectric constant (High-k) film, there is the ALD (Atomic Layer Deposition) film forming method with an excellent recess filling property and step coverage property.

When the hafnium oxide film and zirconium oxide film are formed, as the metal feed materials, the following amide compounds are mainly adopted: tetra-kis ethyl methyl amino hafnium (TEMAH: Hf[N(CH₃)(C₂H₅)]₄), tetra-kis ethyl methyl amino zirconium (TEMAZ: Zr[N(CH₃)(C₂H₅)]₄), etc. H₂O and O₃ are adopted as the oxidant. However, recently, O₃ is mainly adopted as it can have excellent film characteristics. When ALD film formation is carried out, the TEMAH or TEMAZ as the metal material and O₃ as the oxidant are alternately fed into the reaction chamber to form the film (for example, see Patent Reference 1).

The following scheme has been proposed in recent years: by adding (doping) a small quantity of atoms in the high-k film or other metal oxide film, the crystal structure is changed, so that the dielectric constant is further increased. The schemes for adding (doping) a small quantity of atoms in the metal oxide film include a scheme in which the film forming gas and the doping gas are simultaneously blended and fed, and a scheme in which an oxide film using the film forming feed material and an oxide film using the doping feed material are laminated, and, by adjusting the ratio of the film thickness of the various films, it is possible to dope atoms with a prescribed smaller quantity.

### REFERENCES OF PRIOR ART

### Patent References

Patent Reference 1: JP-A-2009-49367

### SUMMARY OF THE INVENTION

### Problems the Invention is to Solve

However, when the film forming gas and the doping gas are simultaneously blended and fed, if the feeding rate of the doping gas is low, it becomes difficult to control the gas feeding ratio to the prescribed value, so that it is difficult to control the doping concentration. On the other hand, for the aforementioned method in which the oxide film using the film forming feed material and the oxide film using the doping feed material are laminated and the ratio of the film thickness of the layers is adjusted, when the film thickness distribution is poor, a significant difference in the distribution of the doping concentration may take place in the substrate. That is, according to the prior art, a difference in the doping concentration distribution and in the film thickness distribution may take place in the substrate, so that a dispersion in the characteristics of the obtained semiconductor devices may take place.

Consequently, the principal purpose of the present invention is to solve the aforementioned problem by providing a method of manufacturing a semiconductor device, a substrate processing apparatus and a semiconductor device, wherein it is possible to form a capacitor insulating film with both a high dielectric constant and a high stability at high temperature.

### Means for Solving the Problems

In order to solve the aforementioned problem, the present invention provides a method of manufacturing a semiconductor device comprising performing a cycle a predetermined number of times to form a film on a substrate, wherein the cycle comprises the steps of: feeding a first feed material containing a first element to a processing chamber where the substrate is accommodated, so that the first feed material is adsorbed on a surface of the substrate; feeding a second feed material containing a second element to the processing chamber after the adsorption of the first feed material, so that the second feed material is adsorbed on the surface of the substrate; feeding a third feed material containing a third element to the processing chamber, so that the surface of the substrate is modified; and removing an atmosphere in the processing chamber, wherein a content of the second element in the film is controlled by adjusting an adsorption quantity of the first feed material and an adsorption quantity of the second feed material with respect to a saturated adsorption quantity of the first feed material adsorbed on the surface of the substrate.

According to another embodiment of the present invention, the present invention provides a method of manufacturing a semiconductor device for forming a predetermined film by sequentially and repeatedly performing a plurality of cycles, each cycle comprising: feeding a first feed material containing a first element to a processing chamber where a substrate is accommodated, so that the first feed material is adsorbed on a surface of the substrate; removing an atmosphere in the processing chamber; feeding a second feed material containing a second element to the processing chamber, so that the second feed material is adsorbed on the surface of the substrate; removing the atmosphere in the processing chamber; feeding a third feed material containing a third element to the processing chamber, so that the surface of the substrate is modified; and removing the atmosphere in the processing chamber, wherein a content of the second element in the film is controlled by adjusting an adsorption quantity of the first feed material and an adsorption quantity of the second feed material with respect to a saturated adsorption quantity of the first feed material adsorbed on the surface of the substrate.

As another embodiment of the present invention, the present invention provides a substrate processing apparatus comprising: a processing chamber where a substrate is accommodated; a first gas supply system that supplies a first gas containing a first element to the substrate; a second gas supply system that supplies a second gas containing a second element to the substrate; a third gas supply system that supplies a third gas containing a third element to the substrate; and a controller that controls the first gas supply system, the second gas supply system, and the third gas supply system so that after the first gas is supplied to the substrate and at least the first element is adsorbed on a surface of the substrate, the second gas is supplied to the substrate and at least the second element is adsorbed on the surface of the substrate, and then the third gas is supplied to the substrate and reacts with the first element and the second element adsorbed on the surface of the substrate to form a predetermined film on the surface of the substrate, wherein, the controller adjusts an adsorption quantity of the first element and an adsorption quantity of the second element with respect to a saturated adsorption quantity of the first element adsorbed on the surface of the substrate, so that a content of the second element in the film is controlled.

### Advantages of the Invention

The present invention provides a method of manufacturing a semiconductor device, a substrate processing apparatus and a semiconductor device, in which a capacitor insulating film is formed with both high dielectric constant and high stability at high temperature.

### BRIEF DESCRIPTION OF THE DRAWINGS

FIG. 1 is a schematic oblique perspective drawing illustrating the constitution of a substrate processing apparatus preferably adopted in an embodiment of the present invention.

FIG. 2 is a schematic diagram illustrating an example of the processing furnace preferably adopted in the embodiment of the present invention and the accompanying members. Especially, it shows the vertical cross-section of a portion of the processing furnace.

FIG. 3 is a cross-sectional view taken across A-A of the processing furnace shown in FIG. 2 and preferably adopted in embodiment of the present invention.

FIG. 4 is a diagram illustrating a film forming sequence related to Embodiment 1 of the present invention.

FIG. 5 is a flow chart illustrating a process related to Embodiment 1 of the present invention.

FIG. 6 is a cross-sectional view illustrating a wafer in the various steps of operation related to Embodiment 1 of the present invention.

FIG. 7 is a diagram illustrating the film forming sequence related to Embodiment 2 of the present invention.

FIG. 8 is a flow chart illustrating a process related to Embodiment 2 of the present invention.

FIG. 9 is a diagram illustrating a relationship between a TEMAH dose and a film thickness related to the present embodiment.

### EMBODIMENT OF THE INVENTION

An embodiment of the present invention will be explained in the following section with reference to the drawings.

### [Overall Configuration of the Apparatus]

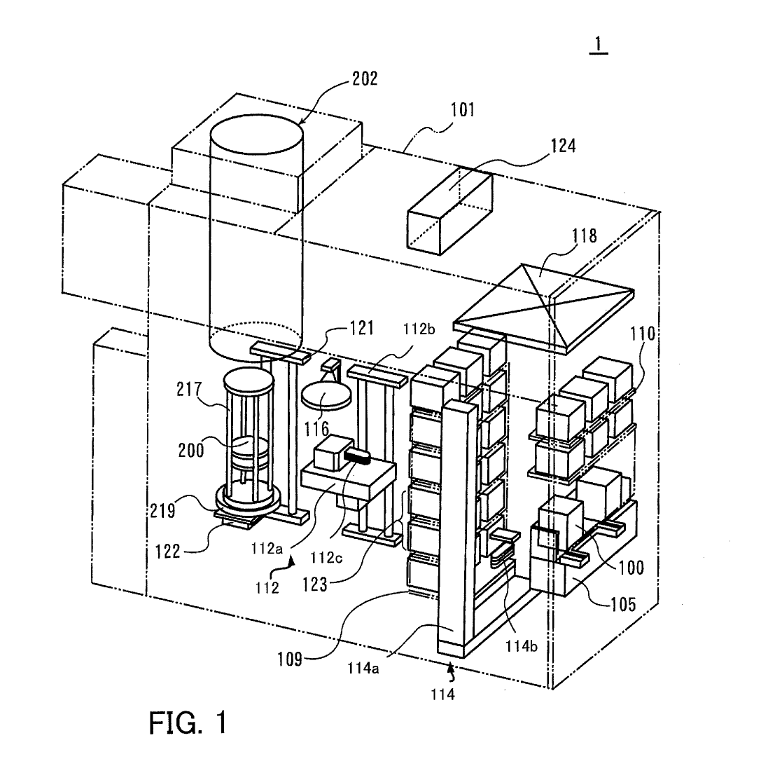

According to the embodiment of the present invention, as an example, a substrate processing apparatus is formed as a semiconductor manufacturing apparatus for embodiment of a processing operation in a manufacturing method of the semiconductor device (IC). In the following explanation, the substrate processing apparatus is taken as a vertical apparatus that carries out oxidation, diffusion processing and CVD processing, etc. for a substrate. FIG. 1 is an oblique perspective drawing of the substrate processing apparatus preferably adopted in an embodiment of the present invention.

The present invention is not limited to the substrate processing apparatus of this embodiment. Other types of the substrate processing apparatus, such as substrate processing apparatus having a cassette-type, hot wall-type, or cold wall-type processing furnace may also be preferably adopted.

As shown in FIG. 1, in the substrate processing apparatus 1, a cassette 100 is adopted as a wafer carrier that accommodates a wafer 200 made of silicon or other material.

The substrate processing apparatus 1 has a case 101.

A cassette stage 105 is arranged on the inner side of the case 101. The cassette 100 is carried by an indoor carrier (not shown in the drawing) onto the cassette stage 105 or carried away from the cassette stage 105.

For the cassette stage 105, by means of the indoor carrier, the wafer 200 is kept in the vertical posture in the cassette 100, and a wafer outlet/inlet of the cassette 100 is oriented upwardly. The cassette stage 105 has a configuration that enables the following operation: the cassette 100 is rotated by 90° in the vertical direction rightward to the rear of the case 101, the wafer 200 in the cassette 100 becomes the horizontal posture, and the wafer outlet/inlet of the cassette 100 becomes facing the rear of the case 101.

A cassette shelf 109 is arranged in the nearly central lower portion in the back-and-forth direction in the case 101. The cassette shelf 109 has a configuration to enable storage of multiple cassettes 100 in multiple rows and columns. In the cassette shelf 109, a transfer shelf 123 is arranged to accommodate the cassettes 100 as the transporting object of a wafer transferring mechanism 112. Also, a standby cassette shelf 110 is arranged above the cassette stage 105, and it has a configuration that enables storage of the standby cassettes 100.

A cassette transporting device 114 is arranged between the cassette stage 105 and the cassette shelf 109. The cassette transporting device 114 comprises a cassette elevator 114a that can hold the cassette 100 and lift it, and a cassette transporting mechanism 114b as the transporting mechanism. By means of the consecutive operations of the cassette elevator 114a and the cassette transporting mechanism 114b, the cassette transporting device 114 can transport the cassette 100 between the cassette stage 105, the cassette shelf 109 and the standby cassette shelf 110.

The wafer transferring mechanism 112 is arranged on the rear of the cassette shelf 109. The wafer transferring mechanism 112 comprises a wafer transferring device 112a that can rotate or direct drive the wafer 200, and a wafer transferring elevator 112b for lifting the wafer transferring device 112a. The wafer transferring elevator 112b is arranged on the right hand side end portion of the pressure-proof case 101. The wafer transferring mechanism 112 has a configuration that enables the following operation: due to the consecutive operations of the wafer transferring device 112a and the wafer transferring elevator 112b, the wafer 200 is picked up by a tweezer 112c of the wafer transferring device 112a, and the wafer 200 is then loaded (charged) in a boat 217, or the wafer is removed (discharged) from the boat 217.

As shown in FIG. 1, a processing furnace 202 is arranged on the upper rear side of the case 101. The lower end portion of the processing furnace 202 can be opened/closed by a furnace port shutter 116 in this configuration.

On the lower side of the processing furnace 202, a boat elevator 121 is arranged for lifting the boat 217 to/from the processing furnace 202. An arm 122 as a connecting jig is connected with the boat elevator 121, and a seal cap 219 is installed horizontally as a lid on the arm 122. The seal cap 219 vertically supports the boat 217, and it has a configuration that enables closure of the lower end portion of the processing furnace 202.

The boat 217 has a plurality of holding members, and it has a configuration that enables multiple wafers 200 (for example, about 50 to 150 pieces) held each horizontally while as a row in the vertical direction with their centers aligned.

As shown in FIG. 1, above the cassette shelf 109, a clean unit 118 is arranged for supplying clear air as cleaned atmosphere. The clean unit 118 comprises a supplying fan and a dustproof filter, and it has a configuration that enables flow of clean air in the interior of the case 101.

A clean unit (not shown in the drawing) for supplying clean air is arranged on the left hand side of the end portion of the case 101 opposite to the side of the wafer transferring elevator 112b and the boat elevator 121, too. The clean unit comprises a supplying fan and a dustproof filter just as the clean unit 118. The clean air supplied from the clean unit flows through near the wafer transferring device 112a and the boat 217, etc., and it is then exhausted outside the case 101.

The operation of the substrate processing apparatus 1 will be explained in the following sections.

As shown in FIG. 1, the cassette 100 is carried in through the cassette outlet/inlet onto the cassette stage 105. In this case, the wafer 200 is kept in vertical posture in the cassette 100, and the cassette is carried such that the wafer outlet/inlet of the cassette 100 is oriented upwardly.

Then, by means of the cassette stage 105, the cassette 100 is rotated rightwardly in the vertical direction by 90° so that the wafer 200 becomes the horizontal posture in the cassette 100, and the wafer outlet/inlet of the cassette 100 is oriented towards the rear of the case 101.

Then, the cassette 100 is automatically transported by the cassette transporting device 114 to the assigned shelf position of the cassette shelf 109 or the standby cassette shelf 110. After storing it temporarily there, the cassette is transferred from the cassette shelf 109 or the standby cassette shelf 110 to the transfer shelf 123 by the cassette transporting device 114, or it is directly transported to the transfer shelf 123.

As the cassette 100 is transferred to the transfer shelf 123, the wafer 200 is picked up by the tweezer 112c of the wafer transferring device 112a from the cassette 100 through the wafer outlet/inlet, and it is loaded (charged) on the boat 217 behind a transfer chamber 124. The wafer transferring device 112a that has sent the wafer 200 to the boat 217 is returned to the cassette 100, and the next wafer 200 is loaded on the boat 217.

As the prescribed number of wafers 200 have been loaded on the boat 217, the lower end portion of the processing furnace 202 closed by the furnace port shutter 116 is opened by the furnace port shutter 116. Then, the seal cap 219 is lifted by the boat elevator 121, so that the boat 217 that holds the group of the wafers 200 is carried (loaded) into the processing furnace 202.

After loading, any desired processing (to be explained later) is carried out for the wafers 200 in the processing furnace 202. After the processing, in a procedure opposite to the procedure, the cassette 100 and the wafers 200 are carried out from the case 101.

### [Configuration of the Processing Furnace]

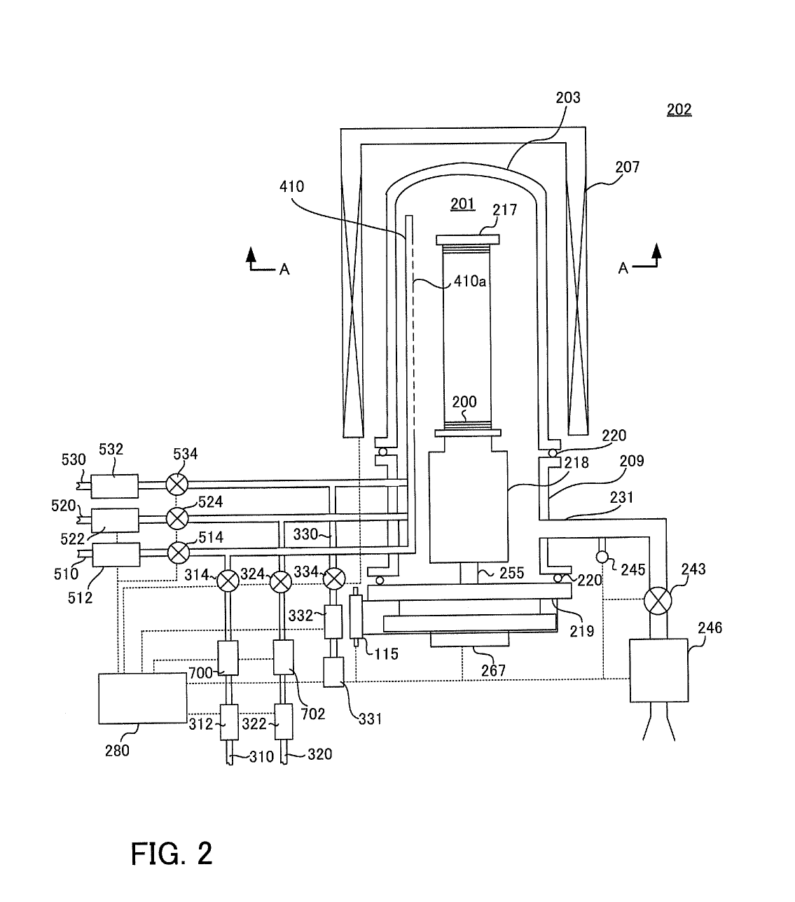

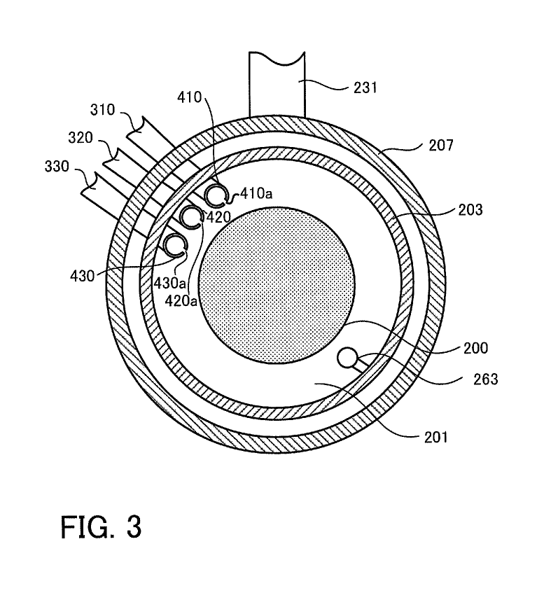

FIG. 2 is a schematic vertical cross-sectional view illustrating the vertical processing furnace of the substrate processing apparatus shown in FIG. 1. FIG. 3 is a cross-sectional view taken across A-A of the processing furnace shown in FIG. 2.

On the inner side of a heater 207 as the heating device (heating means), a reaction tube 203 is arranged as a reaction vessel for processing the wafers 200 as the substrates is arranged. On the lower end of the reaction tube 203, a manifold 209 made of, for example, stainless steel, is engaged; in addition, beneath the reaction tube 203 of its lower end opening, the seal cap 219 is arranged as a furnace port lid that can gastight seal off the lower end opening of the reaction tube 203. The seal cap 219 is in contact with the lower end of the reaction tube 203 from the lower side in the vertical direction. For example, the seal cap 219 is made of stainless steel or other metal, and is formed in a disk shape. On the upper surface of the seal cap 219, an O-ring 220 is arranged as a sealing member in contact with the lower end of the reaction tube 203. A rotating mechanism 267 is arranged for rotating the boat on the side opposite to a processing chamber 201 of the seal cap 219. A rotating shaft 255 of the rotating mechanism 267 goes through the seal cap 219, and it is connected with the boat 217, and it has a configuration that enables rotation of the wafers 200 by rotating the boat 217. The seal cap 219 is formed so as to be lifted in the vertical direction by a boat elevator 115 which is provided as a lift mechanism arranged outside the reaction tube 203. As a result, it is possible to carry the boat 217 into/from the processing chamber 201. The processing furnace 202 comprises at least the heater 207, reaction tube 203, manifold 209, and seal cap 219, and the processing chamber 201 comprises the reaction tube 203, manifold 209, O-ring 220 and seal cap 219.

Ring-shaped flanges are arranged on the lower end portion of the reaction tube 203 and the upper opening end portion of the manifold 209, respectively, and an O-ring 220 is arranged between these flanges to maintain a gastight state between them.

On the seal cap 219, the boat 217 as a substrate holding member (substrate holding means) is erected via the rotating shaft 255 and a boat supporting table 218, and the boat supporting table 218 becomes a holding member that holds the boat 217. Then, the boat 217 is inserted in the processing chamber 201. On the boat 217, multiple wafers 200 for batch processing are carried in several stages in the tube axial direction in the horizontal posture. The heater 207 heats the wafers 200 inserted in the processing chamber 201 to the prescribed temperature.

A plurality of types, or three types in this example, of gases is fed to the processing chamber 201 via three gas feeding pipes 310, 320, 330 as the feeding path. Here, the gas feeding pipes 310, 320, 330 are arranged through the manifold 209. The gas feeding pipe 310 is connected with a gas feeding nozzle 410, the gas feeding pipe 320 is connected with a gas feeding nozzle 420, and the gas feeding pipe 330 is connected with a gas feeding nozzle 430. In the processing chamber 201, the three gas feeding nozzles, that is, the gas feeding nozzle 410, gas feeding nozzle 420, and gas feeding nozzle 430, are arranged in the processing chamber 201.

A film forming gas, such as TEMAH, is fed from the gas feeding pipe 310 into the processing chamber 201. Here, the TEMAH flows through a mass flow controller 312 as a flow rate controller (flow rate control means), a carburetor 700, a valve 314 as a shut-off valve, and the gas feeding nozzle 410 arranged in the processing chamber 201 into the processing chamber 201.

A doping gas, such as tris-dimethylamine silane (TEMAH: SiH[N](CH₃)₂)₃), is fed from the gas feeding pipe 320 to the processing chamber 201. The TEMAH is fed through amass flow controller 322, a carburetor 702, a valve 324 as a shut-off valve, and the gas feeding nozzle 420 arranged in the processing chamber 201 to the processing chamber 201.

An oxidizing gas, such as ozone (O₃), is fed from the gas feeding pipe 330 to the processing chamber 201. Here, O₃ is fed by an ozonizer 331. It is fed through the mass flow controller 332 as a flow rate control means, a valve 334 as a shut-off valve, and the gas feeding nozzle 430 arranged in the processing chamber 201 to the processing chamber 201.

For the gas feeding pipe 310, an inert gas feeding pipe 510 is connected with the downstream side of the valve 314 via amass flow controller 512 and a valve 514. For the gas feeding pipe 320, an inert gas feeding pipe 520 is connected with the downstream side of the valve 324 via a mass flow controller 522 and a shut-off valve 524. For the gas feeding pipe 330, an inert gas feeding pipe 530 is connected with the downstream side of the valve 334 via a mass flow controller 532 and a shut-off valve 534.

A first gas supply system (first gas supply means, first processing gas supply system) mainly comprises the gas feeding pipe 310, the mass flow controller 312, the carburetor 700, the valve 314, and the gas feeding nozzle 410. A first inert gas supply system (first inert gas supply means) mainly comprises the inert gas feeding pipe 510, the mass flow controller 512, and the shut-off valve 514. In addition, a second gas supply system (second gas supply means, second processing gas supply system) mainly comprises the gas feeding pipe 320, the mass flow controller 322, the carburetor 702, the valve 324, and the gas feeding nozzle 420. Also, a second inert gas supply system (second inert gas supply means) mainly comprises the inert gas feeding pipe 520, the mass flow controller 522, and the shut-off valve 524. A third gas supply system (third gas supply means, third processing gas supply system) mainly comprises the gas feeding pipe 330, the ozonizer 331, the mass flow controller 332, the valve 334, and the gas feeding nozzle 430. In addition, a third inert gas supply system (third inert gas supply means) mainly comprises the inert gas feeding pipe 530, the mass flow controller 532, and the shut-off valve 534.

On the reaction tube 203, a gas exhausting pipe 231 is arranged for exhausting the atmosphere in the processing chamber 201. A vacuum pump 246 as an evacuating device is connected via a pressure sensor 245 as a pressure detector for detecting the pressure in the processing chamber 201 and an APC (Auto Pressure Controller) valve 243 as a pressure adjustor (pressure adjusting part) to the gas exhausting pipe 231, and the configuration is such that evacuation can be carried out so that the pressure in the processing chamber 201 becomes the prescribed pressure (vacuum degree). Here, the APC valve 243 is a shut-off valve that can turn on/off the value so that the evacuation of the interior of the processing chamber 201 can be turned on/off, and can adjust the valve openness to adjust the pressure. The gas exhausting system mainly comprises the gas exhausting pipe 231, the APC valve 243, the vacuum pump 246, and the pressure sensor 245.

The gas feeding nozzle 410, the gas feeding nozzle 420 and the gas feeding nozzle 430 are arranged along the stacking direction of the wafers 200 from the low portion to the upper portion of the processing chamber 201. Here, a gas feeding hole 410a is arranged on the gas feeding nozzle 410 to feed several gases, a gas feeding hole 420a is arranged on the gas feeding nozzle 420 to feed several gases, and a gas feeding hole 430a is arranged on the gas feeding nozzle 430 to feed several gases.

In the reaction tube 203, a temperature sensor 263 is arranged as a temperature detector. It has a configuration so that the degree of power feeding to the heater 207 is adjusted on the basis of temperature information detected by the temperature sensor 263, and the temperature in the processing chamber 201 become the desired temperature distribution. Just as the gas feeding nozzles 410, 420, and 430, the temperature sensor 263 is formed in an L-shape along the inner wall of the reaction tube 203.

The boat 217 is arranged in the central portion inside the reaction tube 203, with a plurality of wafers 200 carried thereon as multiple stages with the same interval between them. The boat 217 can be carried by the boat elevator 115 into/from the reaction tube 203. In order to improve the evenness of processing, the boat rotating mechanism 267 is arranged as a rotating device (rotating means) for rotating the boat 217, and, as the boat rotating mechanism 267 rotates, the boat 217 held on the boat supporting table 218 is rotated.

A controller 280 as a control part (control means) is connected with the mass flow controllers 312, 322, 332, 512, 522, 532, the valves 314, 324, 334, 514, 524, 534, the APC valve 243, the ozonizer 331, the heater 207, the vacuum pump 246, the pressure sensor 245, the temperature sensor 263, the boat rotating mechanism 267, the boat elevator 115, etc., and it carries out control for adjustment of the flow rates of the mass flow controllers 312, 322, 332, 512, 522, 532, the on/off operation of the valves 314, 324, 334, 514, 524, 534, the on/off and pressure adjustment operation of the APC valve 243, the operation of the ozonizer 331, the temperature adjustment of the heater 207, start/stop of the vacuum pump 246, the detection operation of the pressure sensor 245 and temperature sensor 263, adjustment of the rotation velocity of the boat rotating mechanism 267, and the lift operation of the boat elevator 115, etc.

According to the conventional CVD method and ALD method, for example, in the case of the CVD method, multiple types of gases containing several elements that construct the film to be formed are simultaneously fed, and, in the case of the ALD method, multiple types of gases containing several elements that construct the film to be formed are alternately fed. By controlling the processing conditions, such as the feeding flow rate, the feeding time, the plasma power, etc., in the feeding operation, the silicon oxide film (SiO film) or the silicon nitride film (SiN film) is formed. In the aforementioned technologies, for example, when a SiO film is formed, the feeding conditions are controlled so that the composition of the film becomes a stoichiometric composition, that is, O/Si≈2, and, when a SiN film is formed, the feeding conditions are controlled so that the composition of the film becomes the stoichiometric composition, that is, N/Si≈1.33.

On the other hand, the feeding conditions can also be controlled with a purpose to have the composition of the formed film become a prescribed composition different from the stoichiometric composition. That is, the feeding conditions can be controlled during the film formation operation to have at least one element among several elements that construct the film to be formed to be surplus with respect to the stoichiometric composition with regard to the other elements. As described above, it is also possible to form a film while controlling the ratio between several elements constructing the film to be formed, that is, the composition of the film. An explanation will be made in the following texts on the case of a sequence example in which the feeding conditions are controlled for multiple types of gases containing different types of elements as they are fed alternately to form a silicon oxide film having the stoichiometric composition or a silicon oxide film with a prescribed composition different from the stoichiometric composition.

### [Manufacturing Method of Semiconductor Device]

In the method for forming an insulating film on a substrate to be explained below, the processing furnace 202 of the aforementioned substrate processing apparatus is used in this step of operation in the manufacturing process of the semiconductor device (device). In the following explanation, the operation of the various parts that form the substrate processing apparatus is controlled by the controller 280.

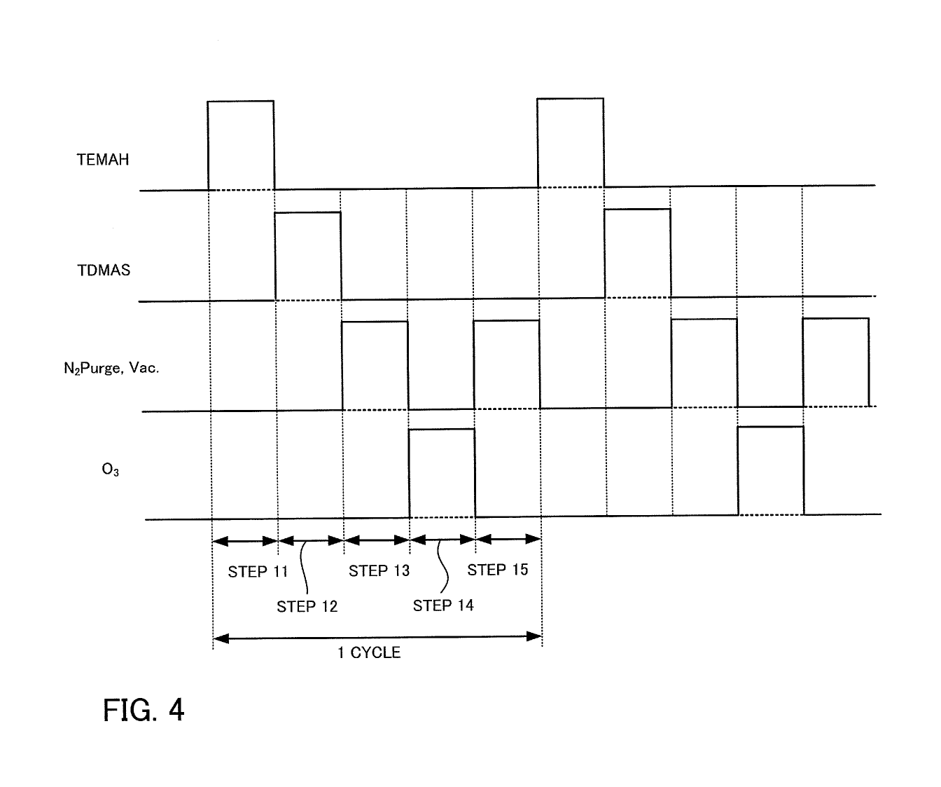

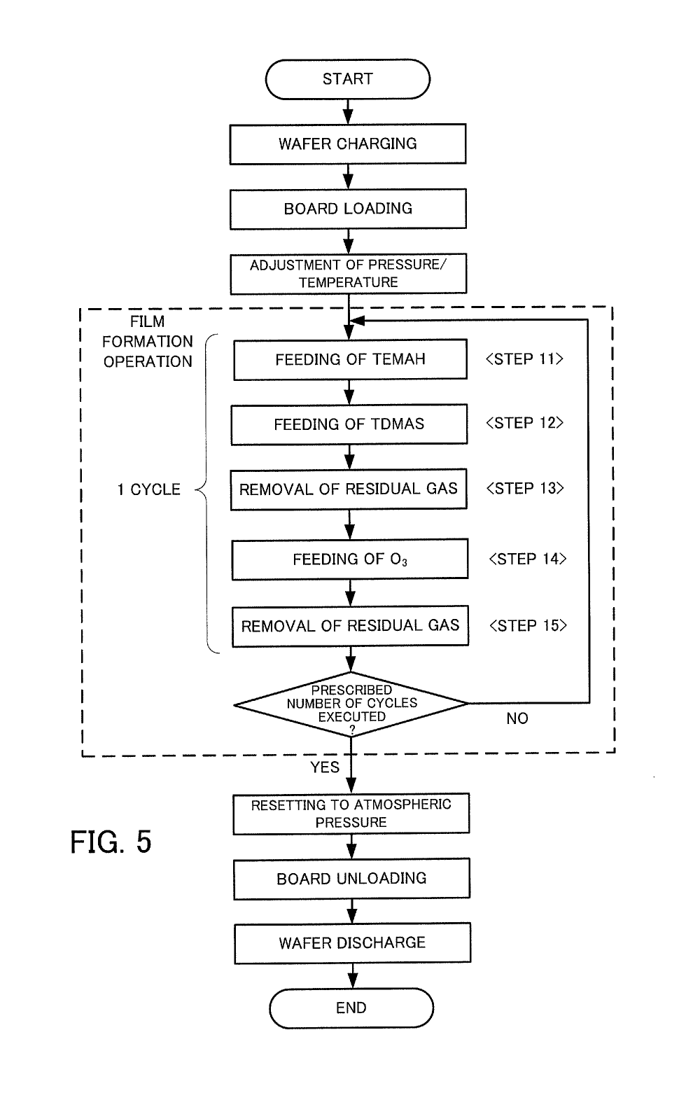

FIG. 4 is a diagram illustrating the film forming sequence in Embodiment 1 of the present invention. FIG. 5 is a flow chart illustrating the process in Embodiment 1 of the present invention.

The film forming feed materials include a Hf-containing gas, such as TEMAH (tetra-kis ethyl methyl amino hafnium Hf[N(CH₃)(C₂H₅)]₄), a Zr-containing gas, such as TEMAZ (tetra-kis ethyl methyl amino zirconium, Zr[N(CH₃)(C₂H₅)]₄), and other organic metal feed materials. As the doping feed materials, it is possible to use TDMAS (tri-dimethylamino silane, SiH[N(CH₃)₂]₃), etc. as a Si-containing gas. As the Al containing gas, it is possible to use TMA (trimethyl aluminum, Al(CH₃)₃), etc. As the oxidant, it is possible to use O-containing gases, such as O₃, H₂O, etc. In addition, as the inert gas, it is possible to use N₂ gas as an example.

### <Substrate Carry-in Process>

First of all, a plurality of wafers 200 is loaded in the boat 217 (wafer charging).

The boat 217 that supports the plurality of wafers 200 is lifted by the boat elevator 115 and is carried into the processing chamber 201 (boat loading). In this state, the seal cap 219 seals off the lower end of the reaction tube 203 via the O-ring 220.

The interior of the processing chamber 201 is evacuated by the vacuum pump 246 so that the interior becomes the desired pressure (vacuum degree). In this case, the pressure in the processing chamber 201 is measured by the pressure sensor 245, and, on the basis of the measured pressure, the APC valve 243 is feedback controlled (pressure adjustment).

Then, the processing chamber 201 is heated by the heater 207 so that the interior of the processing chamber 201 becomes the desired temperature. In this case, on the basis of the temperature information detected by the temperature sensor 263, the power feeding rate is feedback controlled to the heater 207 so that the interior of the processing chamber 201 becomes the desired temperature distribution (temperature adjustment).

Then, the boat 217 is rotated by the boat rotating mechanism 267, so that the wafers 200 are rotated.

### <Film Forming Process>

### (Step 11)

In step 11, as a film forming feed material, the TEMAH is fed as the first feed material through the gas feeding pipe 310.

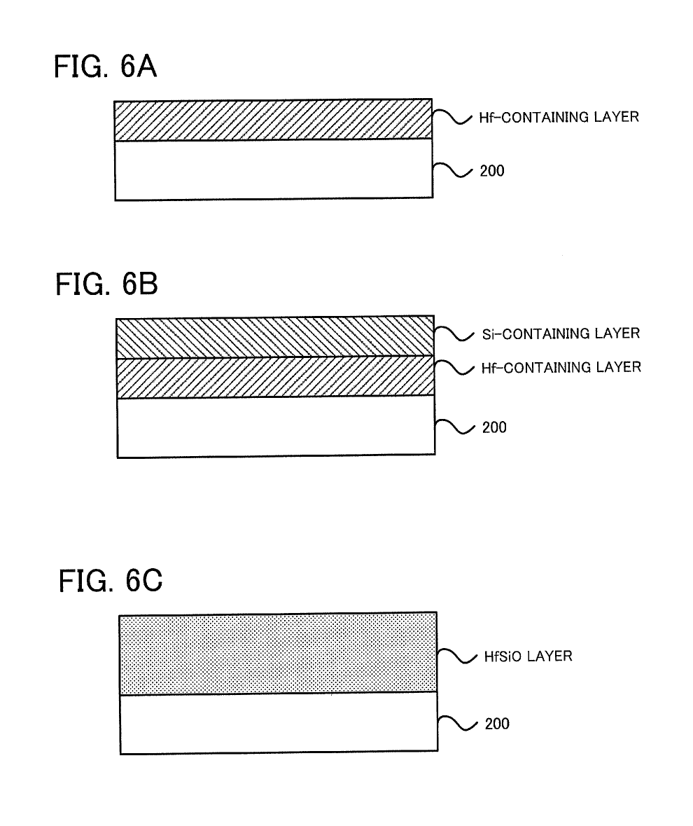

First of all, the shut-off valve 514 arranged on the inert gas feeding pipe 510, the valve 314 arranged on the gas feeding pipe 310, and the valve 243 arranged on the gas exhausting pipe 231 are all opened, so that the inert gas with flow rate adjusted by the mass flow controller 512 from the inert gas feeding pipe 510 and the TEMAH gas with flow rate adjusted by the mass flow controller 312 from the gas feeding pipe 310 and gasified by the carburetor 700 are mixed to a gas mixture, which is fed through the gas feeding hole 410a of the gas feeding nozzle 410 into the processing chamber 201, and the gas mixture is then exhausted from the gas exhausting pipe 231. When the TEMAH gas flows, the APC valve 243 is by appropriately adjusted so that the pressure in the processing chamber 201 is maintained in the range of 30-500 Pa, such as at 100 Pa. The feeding flow rate of the inert gas controlled by the mass flow controller 512 is 5 slm. The time for feeding the TEMAH is set in the range of 1-120 sec. Then, the time for exposing in the atmosphere with pressure increased due to the later suction may be set in the range of 0-4 sec. In this case, the wafer temperature is in the range of 150-250° C., for example, at 250° C. In this case, the gas flowing in the processing chamber 201 is only TEMAH and N₂, Ar, or other inert gas, and there exists no O₃. Consequently, the TEMAH does not lead to gas phase reaction. Instead, surface reaction (chemical adsorption) takes place on the wafer 200, forming an adsorption layer of the feed material (TEMAH) or a Hf layer (hereinafter to be referred to as Hf containing layer) (FIG. 6A). The TEMAH adsorption layer includes, in addition to the continuous adsorption layer of the feed molecules, the discontinuous absorption layer. The Hf layer includes, in addition to the continuous layer made of Hf, the Hf thin film that laminates these layers. In addition, the Hf thin film may also be continuous layer made of Hf.

At the same time, as the shut-off valve 524 and shut-off valve 534 are opened to have the inert gas flow from the inert gas feeding pipe 520 connected with halfway the gas feeding pipe 320 and the inert gas feeding pipe 530 connected with halfway the gas feeding pipe 330, it is possible to prevent the TEMAH gas from returning to the TDMAS side and the O₃ side.

### (Step 12)

In step 12, the valve 314 is closed, and the TDMAS as the second feed material flows as the doping feed material from the gas feeding pipe 320.

First of all, the shut-off valve 524 arranged on the inert gas feeding pipe 520, the valve 324 arranged on the gas feeding pipe 320, and the APC valve 243 arranged on the gas exhausting pipe 231 are all opened, so that the inert gas with flow rate adjusted by the mass flow controller 522 flows from the inert gas feeding pipe 520, and it is mixed with the TDMAS gas with flow rate adjusted by the mass flow controller 322 from the gas feeding pipe 320 and gasified by the carburetor 702 to form a gas mixture, which is fed through the gas feeding hole 420a of the gas feeding nozzle 420 into the processing chamber 201, while it is exhausted from the gas exhausting pipe 231. When the TDMAS gas flows, the internal pressure in the processing chamber 201 is maintained by appropriately adjusting the APC valve 243 to within the range of 30-500 Pa, for example, at 60 Pa. The feeding flow rate of the inert gas controlled by the mass flow controller 522 is 1 slm or lower. The time for feeding the TDMAS is set at 10 sec. The time for exposing in the atmosphere with increased pressure due to the later suction may also be set at 0-10 sec. In this case, the wafer temperature is within the range of 150-250° C., for example, 250° C.

At the same time, as the inert gas flows by opening of the shut-off valve 514 and shut-off valve 534 from the inert gas feeding pipe 510 connected with halfway the gas feeding pipe 310 and the inert gas feeding pipe 530 connected with halfway the gas feeding pipe 330, it is possible to prevent the TDMAS gas from returning to the TEMAH side and the O₃ side.

In this case, the gas flowing in the processing chamber 201 is only the TDMAS and N₂, Ar, or other inert gas, and there exists no O₃. Consequently, the TDMAS does not perform the gas phase reaction. Instead, surface reaction (chemical adsorption) takes place on the wafer 200, forming an adsorption layer of the feed material (TDMAS) or a Si layer (hereinafter to be referred to as Si-containing layer) (FIG. 6B). In addition to a continuous adsorption layer of the feed molecules, the TDMAS adsorption layer also includes a discontinuous adsorption layer. In addition to the continuous layer made of Si, the Si layer also includes Si thin films that laminate these layers. Also, a continuous layer made of Si may be called a Si thin film.

### (Step 13)

After the film is formed, in step 13, the valve 324 is closed, the APC valve 243 is opened, and the processing chamber 201 is evacuated, so that the gas in the processing chamber 201 is exhausted. In this case, if N₂ or other inert gas is fed for purging the processing chamber 201 from the gas feeding pipe 310 as the TEMAH feeding line, the gas feeding pipe 320 as the TDMAS feeding line, and the gas feeding pipe 330 as the O₃ feeding line, and then from the inert gas feeding pipes 510, 520, and 530, it is highly effective in exhausting the residual gas from the processing chamber 201.

### (Step 14)

In step 14, O₃ gas as the third feed material, that is, the oxidant, is fed to flow from the gas feeding pipe 330. First of all, the valve 334 arranged on the gas feeding pipe 330 and the APC valve 243 arranged on the gas exhausting pipe 231 are both opened, so that the O₃ gas with the flow rate adjusted by the mass flow controller 332 from the ozonizer 331 is fed from the gas feeding hole 430a of the gas feeding nozzle 430 to the processing chamber 201, while it is exhausted from the gas exhausting pipe 231. As the O₃ gas is fed to flow, the APC valve 243 is appropriately adjusted so that the internal pressure of the processing chamber 201 is maintained in the range of 30-500 Pa, such as 130 Pa. The feeding flow rate of O₃ controlled by the mass flow controller 332 is 15 slm at 250 g/m³. The time for exposing the wafers 200 to O₃ is 120 sec. In this case, the temperature of the heater 207 is set to ensure that the temperature of the wafers 200 is in the range from 150-250° C., for example, 250° C.

At the same time, the shut-off valve 514 and shut-off valve 524 are opened so that the inert gas flows from the inert gas feeding pipe 510 connected with halfway the gas feeding pipe 310 and the inert gas feeding pipe 520 connected with halfway the gas feeding pipe 320, so that it is possible to prevent the O₃ gas from returning to the TEMAH side and the TDMAS side.

As O₃ is fed, a surface reaction (chemical adsorption) takes place for O₃ with the Hf—Si-containing layer chemically adsorbed on the wafer 200, so that a hafnium silicate (HfSiO) film is formed on the wafer 200 (FIG. 6C).

### (Step 15)

In step 15, the valve 334 of the gas feeding pipe 330 is closed, so that feeding of the O₃ is turned off. Also, while the APC valve 243 of the gas exhausting pipe 231 is opened, the processing chamber 201 is evacuated to 20 Pa or lower by vacuum pump 246, and the residual O₃ is exhausted from the processing chamber 201. In this case, N₂ or other inert gas is fed from the gas feeding pipe 310 as the TEMAH feeding line, the gas feeding pipe 320 as the TDMAS feeding line, and gas feeding pipe 330 as the O₃ feeding line to purge the processing chamber 201, so that the effect in exhausting the residual O₃ can be augmented.

The aforementioned steps 11 to 15 are carried out as a cycle, and at least one or more cycles are performed for film formation and doping, so that an HfSi film with a prescribed thickness is formed on each wafer 200. It is preferred that multiple cycles comprising steps 11 to 15 be carried out repeatedly.

### <Process of Carrying Out the Substrate>

After end of the film formation operation, the internal atmosphere is substituted by N₂ gas, and the pressure in the processing chamber 201 is reset to the ambient pressure (return to atmospheric pressure).

Then, with the aid of the boat elevator 115, the seal cap 219 is lowered to open the lower end of the reaction tube 203, and, at the same time, while being kept in the boat 217, the processed wafers 200 are carried out from the lower end of the reaction tube 203 (boat unloading).

Then, the processed wafers 200 are taken out by the wafer transferring device 112a from the boat 217 (wafer discharge).

### Embodiment 2

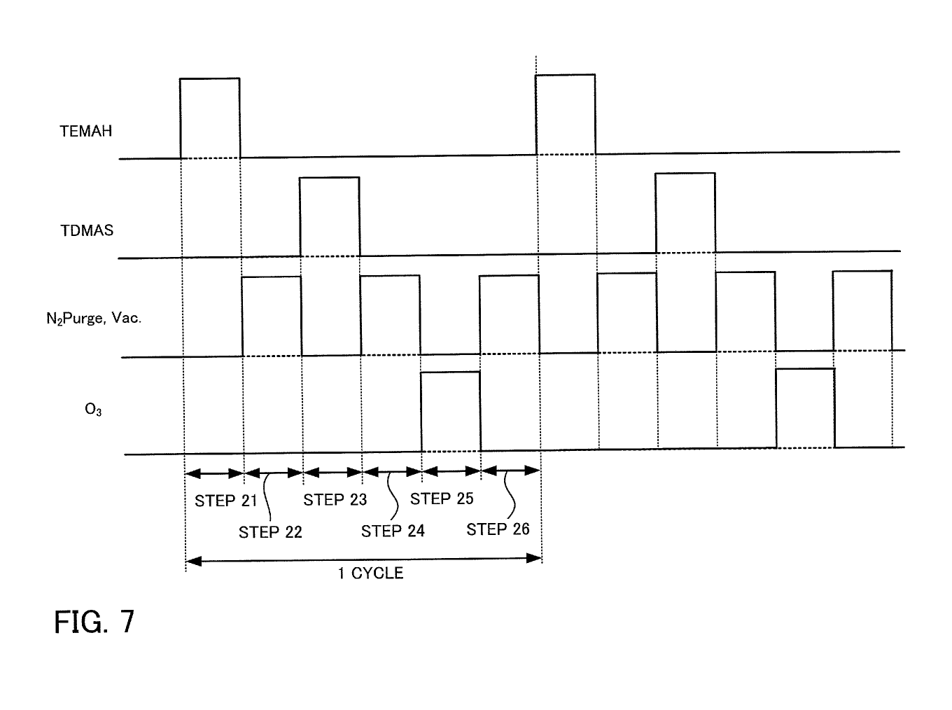

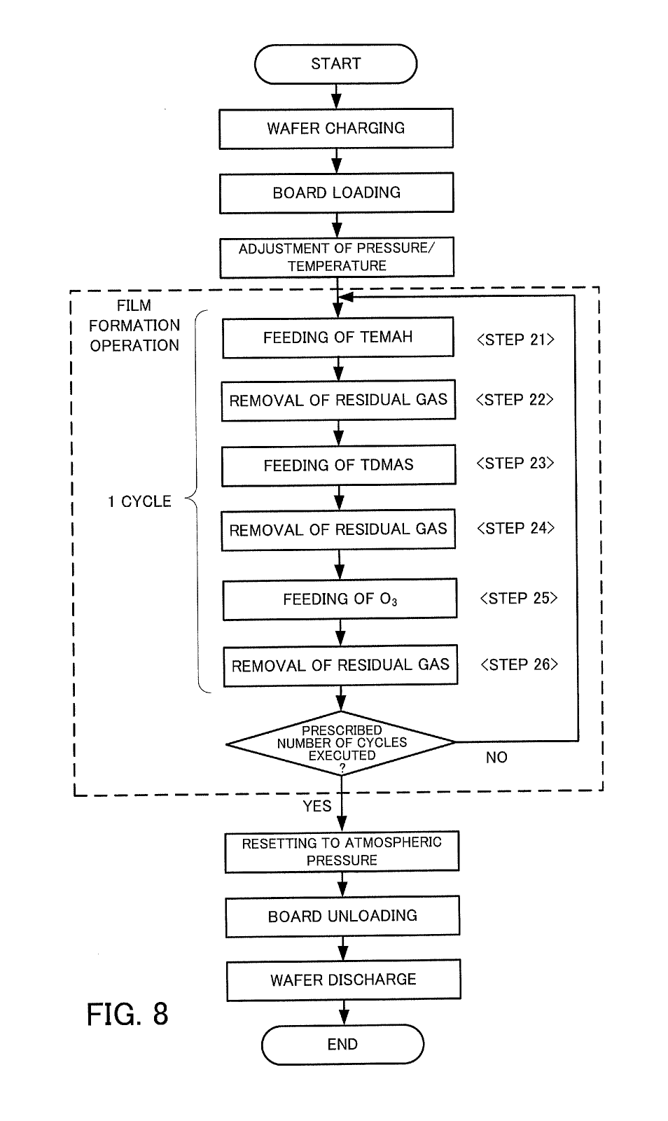

This embodiment will be explained in the following texts with reference to FIGS. 7 and 8. FIG. 7 is a diagram illustrating the film formation sequence in Embodiment 2 of the present invention. FIG. 8 is a flow chart illustrating the process of Embodiment 2 of the present invention. Only features different from those in Embodiment 1 will be explained in the following explanation.

In the film formation step of operation, in the aforementioned Embodiment 1, TEMAH is fed to flow in step 11. TDMAS is fed to flow in step 12. The gas in the processing chamber 201 is exhausted in step 13. O₃ gas is fed to flow in step 14. The residual O₃ in the processing chamber 201 is exhausted in step 15. These steps of operation are carried out as a cycle. On the other hand, Embodiment 2 differs from the aforementioned embodiment in the following features: TEMAH is fed to flow in step 21. The gas in the processing chamber 201 is exhausted in step 22. TDMAS is fed to flow in step 23. The gas in the processing chamber 201 is exhausted in step 24. O₃ gas is fed to flow in step 25. The residual O₃ left in the processing chamber 201 is exhausted in step 26. These steps of operation are carried out as a cycle. The other features of the processing conditions, etc. are the same as that in Embodiment 1.

The relationship between the feeding rate of the film forming gas and that of the doping gas will be explained in the following sections.

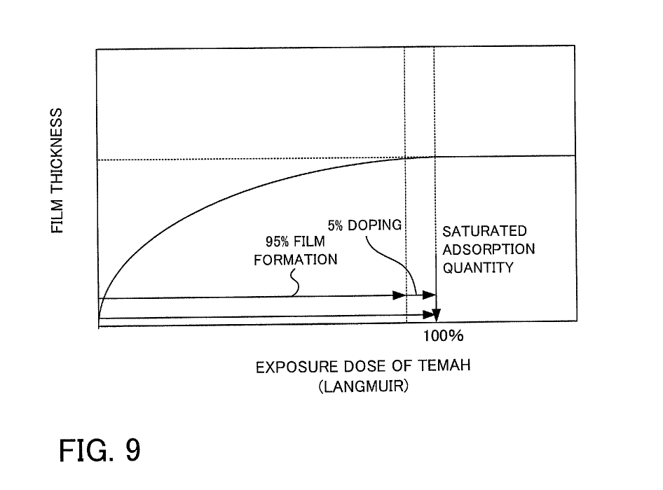

FIG. 9 is a diagram illustrating the relationship between the exposure quantity of TEMAH and the film thickness. The exposure quantity refers to the product of the pressure and feed-in time of the gas fed into the processing chamber 201, and it is represented in units of Langmuir (L, 1 L=10⁻⁶ Torr·sec).

As shown in FIG. 9, for example, suppose 5% doping is to be carried out, 95% of the saturated adsorption quantity of TEMAH (saturated exposure quantity) is carried out by adsorption of the film forming feed material (TEMAH), and the remaining 5% is allotted to adsorption of the doping feed material (TDMAS) as the film forming layer (HfSiO film) containing doping is formed. That is, by adjusting the proportions of the adsorption quantity of TEMAH and the adsorption quantity of TDMAS as the doping feed material with respect to the saturated adsorption quantity of the film forming feed material TEMAH, it is possible to control the feeding rate of the doping feed material, to control the doping quantity in the substrate, and to improve the doping distribution. In this embodiment, exposure is carried out in the order of TEMAH, followed by TDMAS. However, the order for exposure operation may be determined so that the type with better adsorption distribution in the substrate is first adopted for exposure.

That is, according to the present invention, by adjusting the proportions of the adsorption quantity of the film forming feed material and the adsorption quantity of the doping feed material added with respect to the saturated adsorption quantity of the film forming feed material saturated adsorbed on the surface of the substrate, it is possible to control the doping quantity, to control the doping quantity in the substrate and to improve the doping distribution. As a result, it is possible to form a capacitor insulating film that has a high dielectric constant and excellent high-temperature stability.

In addition, in this embodiment, TEMAH is adopted as an example of the Hf containing gas as the film forming feed material. However, the present invention is not limited to the aforementioned scheme. One may also use TEMAZ as the Zr-containing gas, etc.

In this embodiment, as the doping feed material, TDMAS is adopted as an example of the Si-containing gas. However, the present invention is not limited to the aforementioned scheme. One may also use TMA as an Al-containing gas, etc.

According to the present invention, there is no restriction on the types of the high dielectric constant film. In addition to HfSiO film, ZrSiO film, HfAlO film, ZrAlO film, etc., other types of films may also be formed according to the method of the present invention.

In addition, It is preferred that the adsorption quantity of the doping feed material added (doped) with respect to the saturated adsorption quantity of the film forming feed material adsorbed on the surface of the substrate be less than 10% the saturated adsorption quantity of the film forming feed material.

In the configuration of the processing furnace shown in FIG. 2, in the reaction tube 203, gas feeding nozzles 410, 420 and 430 are erected, and the gas exhausting pipe 231 is connected with the lower portion of the reaction tube 203. However, the present invention is not limited to the aforementioned embodiment. For example, instead of the reaction tube 203, one may also use a cylindrical-shaped inner tube and outer tube with upper end closed and with lower end opened. In this case, for the gas feeding nozzle, the inner tube erected in the interior is surrounded by the outer tube, and the gas fed into the processing chamber is exhausted outside the processing chamber through an exhausting port opened at the position on the side wall of the inner tube nearly facing the gas feeding nozzle. The exhausted gas is exhausted outside the reaction tube through a gas exhausting pipe connected with the outer tube. The shape of the exhausting port opened on the inner tube may be a slender slit along the wafer stacking direction, or multiple holes formed along the wafer stacking direction. It is preferred that the exhausting ports be arranged at the height position on the side wall of the inner tube and facing the plurality of wafers, respectively. Consequently, the gas fed from the gas feeding nozzle into the processing chamber flows parallel with the upper surface of the wafers and at near the same gas flow velocity, and it is then exhausted from the exhausting port.

### Preferable Embodiments of the Present Invention

The preferable embodiments of the present invention will be listed in the following sections.

As an embodiment of the present invention, the present invention provides a method of manufacturing a semiconductor device for forming a predetermined film by performing the steps comprising: a step in which a first feed material containing the first element is fed to the processing chamber where the substrate is accommodated, so that the first feed material is adsorbed on a surface of the substrate; a step in which after adsorption of the first feed material, a second feed material containing a second element is fed to the processing chamber, so that the second feed material is adsorbed on the surface of the substrate; a step in which a third feed material containing the third element is fed to the processing chamber, so that the surface of the substrate is modified; and a step in which an atmosphere in the processing chamber is removed, wherein a content of the second element in the film is controlled by adjusting an adsorption quantity of the first feed material and an adsorption quantity of the second feed material with respect to a saturated adsorption quantity of the first feed material adsorbed on the surface of the substrate.

It is preferred that the film formed on the substrate is a high dielectric constant film.

It is preferred that the first element is metal elements including hafnium and zirconium, the second element is silicon or aluminum, and the third element is oxygen.

According to another embodiment of the present invention, the present invention provides a method of manufacturing a semiconductor device for forming a predetermined film by sequentially and repeatedly performing the steps comprising: a first step in which a first feed material containing a first element is fed to a processing chamber where a substrate is accommodated, so that the first feed material is adsorbed on a surface of the substrate; a second step in which an atmosphere in the processing chamber is removed; a third step in which a second feed material containing a second element is fed to the processing chamber, so that the second feed material is adsorbed on the surface of the substrate; a fourth step in which the atmosphere in the processing chamber is removed; a fifth step in which a third feed material containing a third element is fed to the processing chamber, so that the surface of the substrate is modified; and a sixth step in which the atmosphere in the processing chamber is removed, wherein a content of the second element in the film is controlled by adjusting an adsorption quantity of the first feed material and an adsorption quantity of the second feed material with respect to a saturated adsorption quantity of the first feed material adsorbed on the surface of the substrate.

It is preferred that the first feed material has an even adsorption distribution on the surface of the substrate from the second feed material.

As another embodiment of the present invention, the present invention provides a substrate processing apparatus comprising a processing chamber where a substrate is accommodated; a first gas supply system that supplies a first gas containing a first element to the substrate; a second gas supply system that supplies a second gas containing a second element to the substrate; a third gas supply system that supplies a third gas containing a third element to the substrate; and a controller that controls the first gas supply system, the second gas supply system, and the third gas supply system so that after the first gas is supplied to the substrate and at least the first element is adsorbed on a surface of the substrate, the second gas is supplied to the substrate and at least the second element is adsorbed on the surface of the substrate, and then the third gas is supplied to the substrate and reacts with the first element and the second element adsorbed on the surface of the substrate to form a predetermined film on the surface of the substrate, wherein, the controller adjusts an adsorption quantity of the first element and an adsorption quantity of the second element with respect to a saturated adsorption quantity of the first element adsorbed on the surface of the substrate, so that a content of the second element in the film is controlled.

It is preferred that there is also a gas exhausting system for exhausting gas from the processing chamber. The controller controls the gas exhausting system so that the processing chamber is exhausted at least with any of the following timing: a timing after feeding of the first gas to the substrate and before feeding of the third gas to the substrate, or a timing after feeding of the second gas to the substrate and before feeding of the third gas to the substrate.

It is preferred that multiple substrates are stacked and accommodated in the processing chamber.

According to another embodiment of the present invention, the present invention provides a semiconductor device manufactured using the substrate processing apparatus.

The present invention has been explained in the above sections mainly with respect to a vertical batch-type device. However, the present invention is not limited to the aforementioned scheme. One may also adopts a cassette-type device or a horizontal-type device.

### DESCRIPTION OF REFERENCE NUMERALS AND SIGNS

1 substrate processing apparatus
200 wafer
201 processing chamber
202 processing furnace
203 reaction tube
207 heater
231 gas exhausting pipe
243 APC valve
310, 320, 330 gas feeding pipe
312, 322, 332, 512, 522, 532 mass flow controller
331 ozonizer
410, 420, 430 nozzle
410a, 420a, 430a gas feeding hole
510, 520, 530 inert gas feeding pipe
700, 702 carburetor
314, 324, 334, 514, 524, 534 valve
246 vacuum pump
267 boat rotating mechanism
280 controller

1. A method for manufacturing a semiconductor device comprising performing a cycle a predetermined number of times to form a film on a substrate, wherein the cycle comprises the steps of:
feeding a first feed material containing a first element to a processing chamber where the substrate is accommodated, so that the first feed material is adsorbed on a surface of the substrate;
feeding a second feed material containing a second element to the processing chamber after the adsorption of the first feed material, so that the second feed material is adsorbed on the surface of the substrate;
feeding a third feed material containing a third element to the processing chamber, so that the surface of the substrate is modified; and
removing an atmosphere in the processing chamber,
wherein a content of the second element in the film is controlled by adjusting an adsorption quantity of the first feed material and an adsorption quantity of the second feed material with respect to a saturated adsorption quantity of the first feed material adsorbed on the surface of the substrate.

2. The method for manufacturing a semiconductor device according to claim 1, wherein the film formed on the substrate is a high dielectric constant film.

3. The method for manufacturing a semiconductor device according to claim 1, wherein the first element refers to metal elements including hafnium and zirconium, the second element refers to silicon or aluminum, and the third element refers to oxygen.

4. A method for manufacturing a semiconductor device for forming a predetermined film by sequentially and repeatedly performing a plurality of cycles, each cycle comprising:
feeding a first feed material containing a first element to a processing chamber where a substrate is accommodated, so that the first feed material is adsorbed on a surface of the substrate;
removing an atmosphere in the processing chamber;
feeding a second feed material containing a second element to the processing chamber, so that the second feed material is adsorbed on the surface of the substrate;
removing the atmosphere in the processing chamber;
feeding a third feed material containing a third element to the processing chamber, so that the surface of the substrate is modified; and
removing the atmosphere in the processing chamber,
wherein a content of the second element in the film is controlled by adjusting an adsorption quantity of the first feed material and an adsorption quantity of the second feed material with respect to a saturated adsorption quantity of the first feed material adsorbed on the surface of the substrate.

5. A substrate processing apparatus comprising
a processing chamber in which a substrate is accommodated;
a first gas supply system that supplies a first gas containing a first element to the substrate;
a second gas supply system that supplies a second gas containing a second element to the substrate;
a third gas supply system that supplies a third gas containing a third element to the substrate; and
a controller that controls the first gas supply system, the second gas supply system, and the third gas supply system so that after the first gas is supplied to the substrate and at least the first element is adsorbed on a surface of the substrate, the second gas is supplied to the substrate and at least the second element is adsorbed on the surface of the substrate, and then the third gas is supplied to the substrate and reacts with the first element and the second element adsorbed on the surface of the substrate to form a predetermined film on the surface of the substrate, wherein,
the controller adjusts an adsorption quantity of the first element and an adsorption quantity of the second element with respect to a saturated adsorption quantity of the first element adsorbed on the surface of the substrate, so that a content of the second element in the film is controlled.

6. The substrate processing apparatus according to claim 5, further comprising
a gas exhausting system for exhausting the gas from the processing chamber, wherein
the controller controls the gas exhausting system so that the processing chamber is exhausted at least with any of the following timing: a timing after feeding of the first gas to the substrate and before feeding of the third gas to the substrate, or a timing after feeding of the second gas to the substrate and before feeding of the third gas to the substrate.

7. The substrate processing apparatus according to claim 5, wherein a plurality of substrates are stacked and accommodated in the processing chamber.

8. A semiconductor device manufactured using the substrate processing apparatus according to claim 5.
